(19) United States
(12) Patent Application Publication
(10) Pub. No.: US 2008/0057656 A1
(43) Pub. Date: Mar. 6, 2008

(54) Method of Manufacturing Semiconductor Device

(76) Inventor: JIN HA PARK, Echcon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/849,138

(22) Filed: Aug. 31, 2007

(30) Foreign Application Priority Data
Aug. 31, 2006 (KR) 10-2006-0083346

(51) Int. Cl. H01L 21/336

(52) U.S. Cl. 438/303; 257/E21.409

(57) ABSTRACT

A method is provided for forming a lightly-doped drain (LDD) area of a transistor by means of a single implant process. The method includes implanting a dopant under a process condition of an ;implantation energy of 10 KeV or less and a dose of 1.5×10¹⁴ to 3.0×10¹⁴ ions/cm². The method makes it possible to simplify the process thereof, reduce the process time thereof, and improve the breakdown voltage of a device. The method can be used for 180 nm-grade or smaller flash memory.

### CROSS-REFERENCE TO RELATED APPLICATION

The present application claims the benefit under 35 U.S.C. §119 of Korean Patent Application No. 10-2006-0083346, filed Aug. 31, 2006, which is hereby incorporated by reference in its entirety.

### BACKGROUND

High-capacity flash memory devices have become important as personal digital assistants (PDAs), cell phones, and a MP3s become more popular. As demands of flash memory increase, so has the need for compactization.

A flash memory includes a cell transistor in a cell area, and a high voltage transistor and a logic transistor in a periphery area. The high voltage transistor is used in programming or erasing the cell transistor, and the logic transistor is used in controlling a decoder and an amplifier.

A lightly-doped drain (LDD) area in the logic transistor included in a 180 nm-grade flash memory can be formed by means of a dual implant process. In other words, in a first implant process, ions of Ge, which is a IV group-based dopant and has mass of 73 atomic mass unit (AMU), are implanted with a dose of 4.1×10¹⁴ ions/cm² at an implantation energy of 15 KeV so that the surface of a Si substrate becomes amorphous, while minimizing the influence on the device. Because Ge ions are implanted, BF₂ ions implanted in a later process can be controlled to have a shallower a profile. Accordingly, the BF₂ ion of which mass is 49 AMU is implanted through the surface of Si substrate into which the Ge ions have been implanted so that a desired LDD area can be formed on the surface of the Si substrate.

The LDD area of the related art is formed by means of the dual implant process incorporating the implant process of the Ge ions for making the surface of the Si substrate amorphous. However, this process becomes complicated and the processing time is increased.

Such a problem of the related art may be due to the absence of an ion implant device using a low energy below 10 KeV.

Furthermore, unnecessary Ge ion is implanted into the LDD area, causing a problem that breakdown voltage characteristics may become deteriorated.

### BRIEF SUMMARY

Embodiments of the present invention provide a method of manufacturing a semiconductor device capable of improving breakdown voltage characteristics.

A method of manufacturing a semiconductor device according to an embodiment includes: forming a gate on a substrate; forming a lightly-doped drain (LDD) area through a single implant process implanting a dopant at an energy of 10 KeV or less using the gate as a mask; forming a spacer on the side of the gate; and forming a source/drain region in the lower area of the LDD area using the spacer and the gate as a mask.

### BRIEF DESCRIPTION OF THE DRAWINGS

FIG. 1 is a cross-sectional view showing a structure of a logic transistor of a flash memory according to an embodiment of the present invention.

FIG. 2 is graph showing a density profile when an energy of 7 KeV is used.

FIG. 3 is a graph showing a density profile when an energy of 5 KeV is used.

FIG. 4 is a graph showing a driving current according to a threshold voltage.

FIG. 5 is a graph showing a driving current according to a device size.

FIG. 6 is a graph showing a threshold voltage according to a device size.

FIG. 7 is a graph showing a breakdown voltage according to each split.

### DETAILED DESCRIPTION

Hereinafter, embodiments of the present invention will be described in detail with reference to the accompanying drawings.

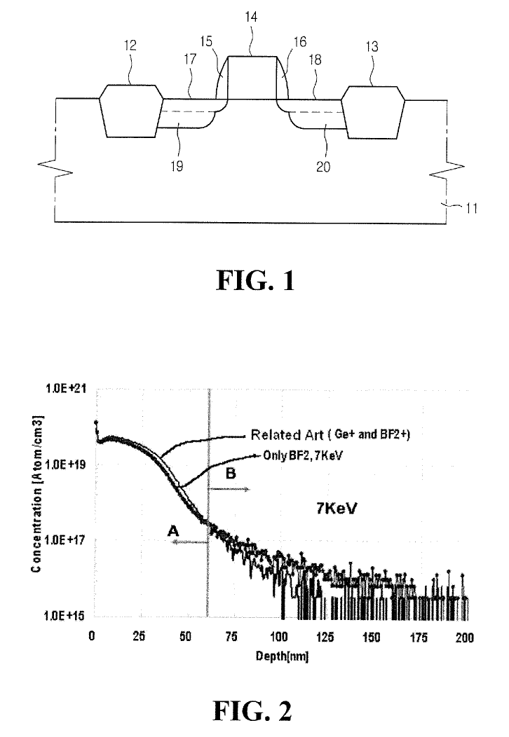

FIG. 1 is a cross-sectional view showing a structure of a logic transistor of a flash memory according to an embodiment of the present invention.

As shown in FIG. 1, the logic transistor is formed on a substrate having an active area and a field area. The active area is the area provided with unit transistors, and the field area is the area for insulating between each unit transistor.

Field layers 12 and 13 for defining the active area on a silicon Si substrate 11 are formed in the field area.

A gate 14 including a gate insulating layer (not shown) and a floating gate (not shown) is formed in the active area.

Lightly doped drain (LDD) areas 17 and 18 are formed near the surfaces of the substrate 11 at sides of the gate 14 by means of an ion implant process using an impurity ion implanted at a low concentration by using the gate 14 as a mask.

Spacers 15 and 16 are formed on the sidewalls of the gate 14.

Source/drain areas 19 and 20 are formed relatively deep in the substrate 11 at the sides of the spacers 15 and 16, that is, in the lower area of the LDD areas 17 and 18, by means of an ion implant process using an impurity ion implanted at high concentration by using the gate 14 and the spacers 15 and 16 as a mask.

In particular, the LDD areas 17 and 18 are very sensitive areas in relation with the device characteristics so that they should be precisely formed in the desired place on the surface of the substrate 11.

However, in the related art, since an ion implant device using low energy has not been developed, low-concentration impurity has been implanted, inevitably giving variety to the process thereof, as well as a separate implant process has been added for making the surface of the Si substrate amorphous before the impurity implant for the LDD region.

Such a problem has been recently addressed by the development of an ion implant device using low energy.

However, an optimal method for forming the LDD area using the ion implant device has not been yet proposed.

Embodiments of the present invention provide a method for forming an optimal LDD area using an ion implant device using low energy (below 10 KeV).

Hereinafter, an experimental method and the result thereof for a method for forming the optimal LDD area will be described.

To form a profile the same as the LDD area by means of the dual implant process of the related art using the ion implant device using low energy can be regarded as an optimal profile so that the following experiment focuses on obtaining the process conditions for having a profile the same as the LDD area by means of the dual implant process of the related art.

First, ion implant processes at the energy of 7 KeV, 5 KeV, 3 KeV, and 2.5 KeV are performed for obtaining an optimal energy and then, SIMS profiles are compared. According to one embodiment, the dopant is BF₂⁺.

As shown in FIG. 2, it is appreciated that when energy is 7 KeV, the case using only BF₂⁺ at the depth of 60 nm or more has a deeper profile than the related art, that is, the case of the dual implant process (including the implant of Ge⁺ and the implant of BF₂⁺).

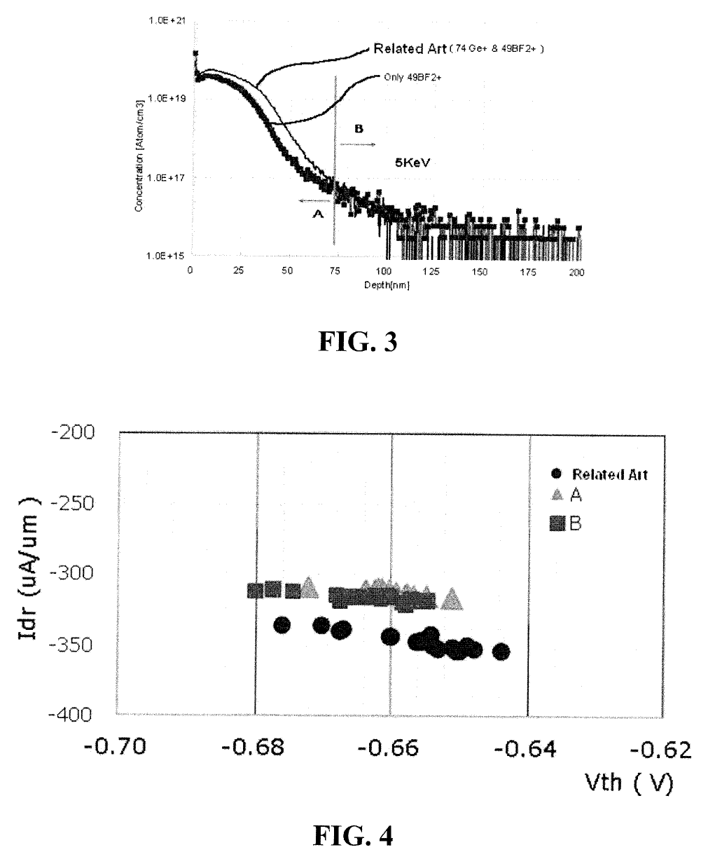

As compared to this, as shown in FIG. 3, it is appreciated that when energy is 5 KeV, the case using only BF₂⁺ from the depth of 75 nm or more has the same profile as the related art.

As a result of this experiment, 5 KeV can be determined to be the optimal energy.

TABLE 1

| | | Dose | Energy | | |
|---|---|---|---|---|---|
| Split | Dopant | (ion/cm²) | (KeV) | Tilt/Torsion | Reference |
| Related art | 73Ge⁺ | 4.1 × 10¹⁴ | 15 | 0/0 | |
| | 49BF₂⁺ | 3.0 × 10¹⁴ | 10 | 0/0 | |
| A | 49BF₂⁺ | 1.8 × 10¹⁴ | 5 | 0/0 | Omission of Ge |
| | | | | | implant |
| B | 49BF₂⁺ | 2.1 × 10¹⁴ | 5 | 0/0 | Omission of Ge |
| | | | | | implant |

As shown in the Table 1, the related art is constituted by a dual implant process comprising a first implant process implanting the 73 Ge dopant under a process condition of a dose of 4.1×10¹⁴ ions/cm² using an implantation energy of 15 KeV, and a second implant process implanting the 49BF₂⁺ dopant under a process condition of a dose of 3.0×10¹⁴ ions/cm² using an implantation energy of 10 KeV.

In contrast, the split A according to an embodiment, implants 49BF₂⁺ dopant under a process condition of a dose of 1.8×10¹⁴ ions/cm² using an implantation energy of 5 KeV, and the split B, according to an embodiment, implants 49BF₂⁺ dopant under a process condition of a dose of 2.1×10¹⁴ ions/cm² using an implantation energy of 5 KeV.

The split A and the split B are the same in view of the dopant and the energy, but different only in view of the amount of dose. Also, differing from the related art, both the split A and the split B omit the ion implant process of the Ge dopant but implement only the single implant process, implanting only the BF dopant.

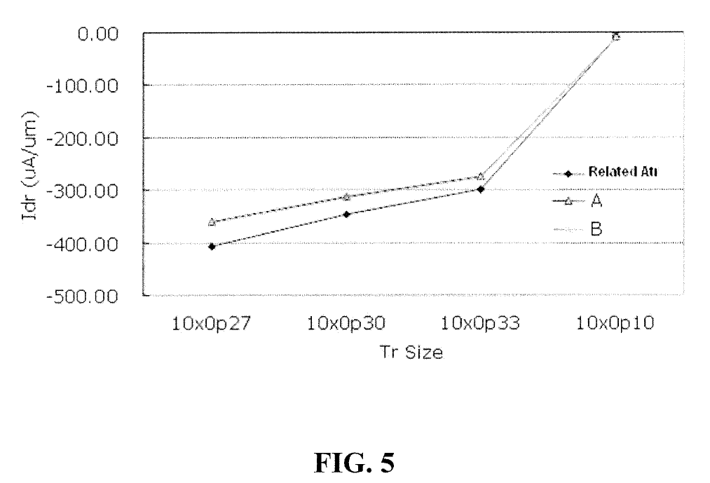

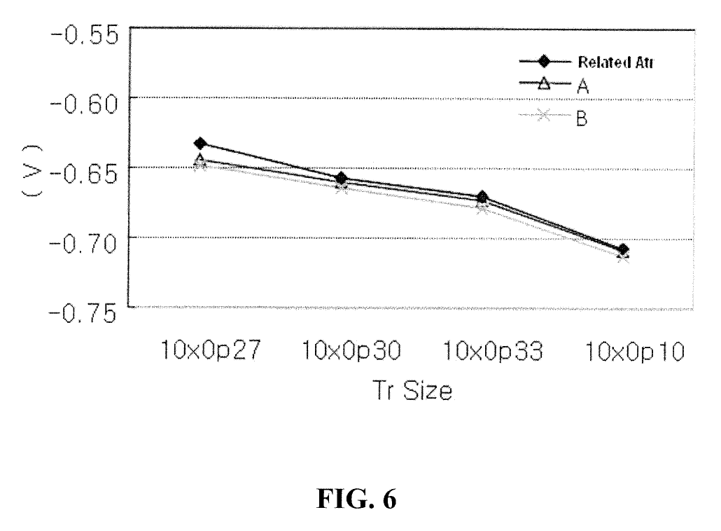

After applying each condition as described above to the substrate, the experimental data illustrated in FIGS. 4 to 7 can be obtained.

As shown in FIGS. 4 to 6, it can be appreciated that an operating current I_{dr} or a threshold voltage Vₜₕ is similar or is slightly more improved in the split A and the split B as compared to the related art.

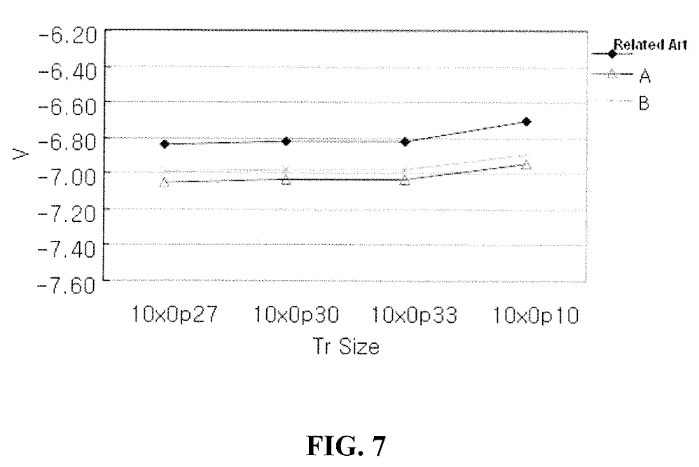

However, as shown in FIG. 7, the breakdown voltage is improved by about 3% in the split A and the split B as compared to the related art. In connection with the improvement of the breakdown voltage as described above, the Ge dopant used in the related art causes a lattice damage on the surface of the silicon substrate, but this is not sufficiently recovered in the subsequent process so that the breakdown voltage is deteriorated. In contrast, embodiments of the present invention omit the process of implanting the Ge dopant, so that the breakdown voltage is further improved to that extent.

Based on the above illustrated results, the process of implanting the Ge dopant can be omitted and a single implant process can be performed implanting 49BF₂⁺ dopant under a process condition of a dose in a range of 1.5×10¹⁴ to 3.0×10¹⁴ and an implantation energy of 1 to 10 KeV. Accordingly, it is possible to form an optimal LDD area.

As described above, process conditions for forming an optimal LDD area using an ion implant device using low energy are provided, making it possible to simplify the process thereof, reduce the process time thereof, and improve the breakdown voltage.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device, comprising:
forming a gate on a substrate;
forming a lightly doped drain (LDD) area through a single implant process implanting a dopant at an implantation energy of 10 KeV or less using the gate as a mask;
forming a spacer on the side of the gate; and
forming a source/drain area in the LDD area using the spacer and the gate as a mask.

2. The method according to claim 1, wherein the dopant is 49BF₂⁺.

3. The method according to claim 1, wherein the dopant is implanted at a dose having a range of 1.5×10¹⁴ to 3.0×10¹⁴ ions/cm².

4. The method according to claim 1, wherein the implantation energy is in a range of 1 to 10 KeV.

5. The method according to claim 1, wherein the single implant process is an implant process using only 49BF₂⁺ dopant.
